(19) United States
(12) Patent Application Publication
(10) Pub. No.: US 2004/0115957 A1
(43) Pub. Date: Jun. 17, 2004

(54) Apparatus and method for enhancing wet stripping of photoresist

(75) Inventor: Po-Jen Chen, Kaohsiung (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/322,408

(22) Filed: Dec. 17, 2002

(51) Int. Cl. H01L 21/302

(52) U.S. Cl. 438/784

(57) ABSTRACT

An apparatus and method for enhancing uniformity in the spread of a process chemical such as a liquid strip chemical or solvent over the surface of a wafer to enhance contact of all areas of the wafer with the chemical, such as during the removal or stripping of photoresist from the wafer. The apparatus includes a wafer chuck having a heater for heating the wafer chuck and a wafer supported on the chuck. The wafer chuck and wafer are initially heated to a desired target temperature which is substantially the same as the temperature of the process chemical, after which the process chemical is dispensed onto the surface of the rotating wafer.

### FIELD OF THE INVENTION

The present invention relates to photolithography processes used in the formation of integrated circuit (IC) patterns on photoresist in the fabrication of semiconductor integrated circuits. More particularly, the present invention relates to an apparatus and method for enhancing wet stripping of photoresist from a wafer by maintaining a low viscosity of a strip chemical or solvent dispensed onto the wafer to enhance spread of the strip chemical or solvent from the center to the edge of the wafer.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

Photoresist materials are coated onto the surface of a wafer by dispensing a photoresist fluid typically on the center of the wafer as the wafer rotates at high speeds within a stationary bowl or coater cup. The coater cup catches excess fluids and particles ejected from the rotating wafer during application of the photoresist. The photoresist fluid dispensed onto the center of the wafer is spread outwardly toward the edges of the wafer by surface tension generated by the centrifugal force of the rotating wafer. This facilitates uniform application of the liquid photoresist on the entire surface of the wafer.

During the photolithography step of semiconductor production, light energy is applied through a reticle mask onto the photoresist material previously deposited on the wafer to define circuit patterns which will be etched in a subsequent processing step to define the circuits on the wafer. A reticle is a transparent plate patterned with a circuit image to be formed in the photoresist coating on the wafer. A reticle contains the circuit pattern image for only a few of the die on a wafer, such as four die, for example, and thus, must be stepped and repeated across the entire surface of the wafer. In contrast, a photomask, or mask, includes the circuit pattern image for all of the die on a wafer and requires only one exposure to transfer the circuit pattern image for all of the dies to the wafer.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

Spin coating of photoresist on wafers, as well as the other steps in the photolithography process, is carried out in an automated coater/developer track system using wafer handling equipment which transport the wafers between the various photolithography operation stations, such as vapor prime resist spin coat, develop, baking and chilling stations. Robotic handling of the wafers minimizes particle generation and wafer damage. Automated wafer tracks enable various processing operations to be carried out simultaneously. Two types of automated track systems widely used in the industry are the TEL (Tokyo Electron Limited) track and the SVG (Silicon Valley Group) track.

A typical method of forming a circuit pattern on a wafer includes introducing the wafer into the automated track system and then spin-coating a photoresist layer onto the wafer. The photoresist is next cured by conducting a soft bake process. After it is cooled, the wafer is placed in an exposure apparatus, such as a stepper, which aligns the wafer with an array of die patterns etched on the typically chrome-coated quartz reticle. When properly aligned and focused, the stepper exposes a small area of the wafer, then shifts or “steps” to the next field and repeats the process until the entire wafer surface has been exposed to the die patterns on the reticle. The photoresist is exposed to light through the reticle in the circuit image pattern. Exposure of the photoresist to this image pattern cross-links and hardens the resist in the circuit pattern. After the aligning and exposing step, the wafer is exposed to post-exposure baking and then is developed and hard-baked to develop the photoresist pattern.

The circuit pattern defined by the developed and hardened photoresist is next transferred to the underlying metal conductive layer using a metal etching process, in which metal over the entire surface of the wafer and not covered by the cross-linked photoresist is etched away from the wafer with the metal under the cross-linked photoresist that defines the circuit pattern protected from the etchant. As a result, a well-defined pattern of metallic microelectronic circuits which closely approximates the cross-linked photoresist circuit pattern remains in the metal layer.

After the circuit pattern is etched in the metal layer, residual photoresist remains on the wafer. During the metal etch process, some of the photoresist residue becomes sputtered from the wafer and redeposited onto the side walls of the metal circuit structures. Additionally, some of the photoresist reacts with etch reactants and products to form polymeric residue. These photoresist residues must be removed from the wafer prior to completing the IC fabrication process.

Typically, the wafer is subjected to a two-step process for removal of the photoresist reactants and residue from the wafer. The first step in the process is an oxygen plasma (plasma ashing) step which removes most or all of the unreacted residual photoresist from the wafer. The second step is a wet strip process which is used to remove the polymeric residue from the wafer. During the oxygen plasma step, the unreacted residual photoresist reacts with the oxygen to form volatile compounds which leave the wafer surface. However, the gases present in the oxygen plasma tend to react with and harden some of the residual photoresist, which remains on the wafer. In the subsequent wet strip step, a solvent solution is used to remove the hardened residual photoresist generated during the oxygen plasma step, as well as the polymeric residue formed from the photoresist during the metal etch process, from the wafer and circuit structures.

FIG. 1 is a cross-sectional, partially schematic view of a typical conventional wafer support 10 for supporting a wafer 18 in a strip chamber (not shown) during a photoresist wet strip process. The wafer support 10 typically includes a shaft 12 which is connected to a chuck 16 through a coupling 14. The wafer 18 is supported on the chuck 16. As the shaft 12 rotates the chuck 16 and the wafer 18 supported thereon, a liquid strip chemical 20, which is an organic solvent, is dispensed from a dispenser 22 onto the upper surface of the wafer 18, at the center thereof. The strip chemical 20 spreads outwardly over the surface of the wafer 18 due to the centrifugal force exerted on the strip chemical 20 by the spinning wafer 18. In this manner, the dispensed strip chemical 20 is distributed from the center toward the edge of the wafer 18. The strip chemical 20 removes residual photoresist (not shown) from the surface of the wafer 18, including circuit lines etched in the conductive layer on the wafer 18 in a previous metal etch process, prior to continued fabrication of integrated circuits on the wafer 18.

During the wet stripping process outlined above, the strip chemical is typically heated prior to being dispensed onto the surface of the wafer. In contrast, the wafer typically remains at room temperature as the strip chemical is dispensed onto the wafer. As a result, the heated strip chemical is substantially cooled upon contact with the wafer, and this decreases the viscosity of the strip chemical. Consequently, distribution of the strip chemical in a uniform spread from the center to the edge of the wafer is hindered, resulting in more effective removal of the photoresist residue from the central areas as compared to the peripheral areas of the wafer. Accordingly, a method is needed for maintaining the elevated temperature of a strip chemical during a wet stripping operation in order to maintain the chemical at a low viscosity for enhanced spread of the chemical over the surface of the wafer.

An object of the present invention is to provide an apparatus and method which is suitable for maintaining a low viscosity of a strip chemical during the stripping of photoresist from a wafer.

Another object of the present invention is to provide an apparatus and method for facilitating a substantially uniform spread of a liquid process chemical from the center region to the edge regions of a wafer, which apparatus and method is not limited to use in photoresist stripping processes.

Another object of the present invention is to provide an apparatus and method which is suitable for heating a wafer prior to and during dispensing of a heated strip chemical onto the wafer for the enhanced stripping or removal of photoresist from the wafer.

Still another object of the present invention is to provide an apparatus and method which is suitable for enhancing uniformity in the spread or distribution of a strip chemical on the surface of a wafer by lowering or maintaining a low viscosity of the liquid strip chemical.

Yet another object of the present invention is to provide an apparatus and method which utilizes a heated wafer chuck to facilitate heating a wafer to a target temperature substantially equal to the temperature of a liquid strip chemical dispensed onto the wafer during a photoresist stripping process.

A still further object of the present invention is to provide a method for enhancing distribution of a liquid process chemical over the surface of a wafer, which method includes heating the wafer to a target temperature; heating the process chemical to the target temperature; rotating the wafer; and dispensing the strip chemical onto the wafer as the wafer is rotated.

Yet another object of the present invention is to provide a method for improving the removal of photoresist from a wafer.

### SUMMARY OF THE INVENTION

In accordance with these and other objects and advantages, the present invention is generally directed to an apparatus and method for enhancing uniformity in the spread of a process chemical such as a liquid strip chemical or solvent over the surface of a wafer to enhance contact of all areas of the wafer with the chemical, such as during the removal or stripping of photoresist from the wafer. The apparatus includes a wafer chuck having a heater for heating the wafer chuck and a wafer supported on the chuck. The wafer chuck and wafer are initially heated to a desired target temperature which is substantially the same as the temperature of the process chemical, after which the process chemical is dispensed onto the surface of the rotating wafer. The process chemical is maintained at the desired target temperature on the heated wafer to maintain a low viscosity of the process chemical and thus, enhance uniformity in distribution or spread of the process chemical from the center to the peripheral regions on the wafer surface.

### BRIEF DESCRIPTION OF THE DRAWINGS

The invention will now be described, by way of example, with reference to the accompanying drawings, in which:

FIG. 1 is a schematic view, partially in cross-section, of a typical conventional wafer support for supporting a wafer during a photoresist stripping process;

FIG. 2 is a schematic view, partially in section, of a wafer support in implementation of the present invention for supporting a wafer during a semiconductor fabrication process;

FIG. 3 is a flow diagram according to a method of the present invention; and

FIG. 4 is a top view of a rotating wafer, more particularly illustrating distribution of a process chemical from the center to the peripheral regions on the wafer surface in implementation of the present invention.

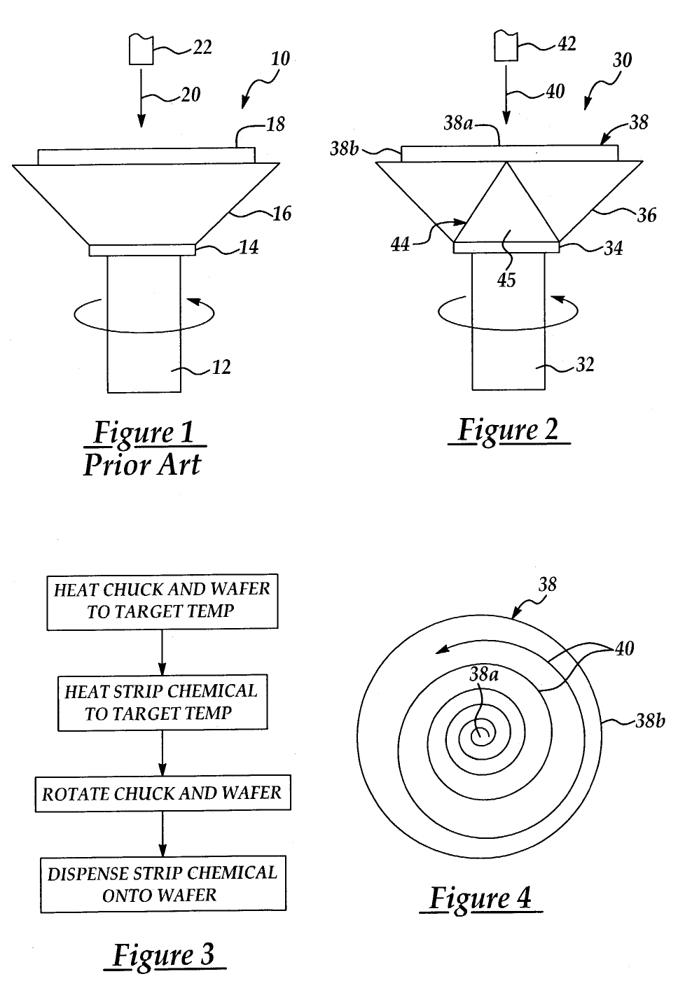

### DESCRIPTION OF THE PREFERRED EMBODIMENTS

The present invention has particularly beneficial utility in enhancing removal of photoresist from a wafer by heating and maintaining a low viscosity of a strip chemical or solvent after the chemical is dispensed onto the surface of the wafer in order to facilitate a substantially uniform spread of the strip chemical or solvent from the center to the edge of the wafer. However, the invention is not so limited in application, and while references may be made to such photoresist removal and strip chemical or solvent, the present invention is more generally applicable to enhancing the spread or distribution of any type of liquid process chemical over the surface of a wafer during the fabrication of integrated circuits on the wafer.

Referring initially to FIG. 2, a wafer support 30 in accordance with the present invention is typically mounted in a process chamber (not shown) for the processing of semiconductor wafers 38. For example, the wafer support 30 is particularly adapted for a spin-type wet strip photoresist strip chamber available from the SEZ corporation of Phoenix, Az. The wafer support 30 typically includes a shaft 32 which is connected to a chuck 36 through a coupling 34. The upper surface of the chuck 36 supports the wafer 38. A chuck heater 44, typically having a generally inverted cone-shaped heater body 45, is provided inside and in thermal contact with the chuck 36, according to the knowledge of those skilled in the art. A chemical dispenser 42 is disposed above the chuck 36 for dispensing a process chemical 40 onto the upper surface of the wafer 38, at the center thereof, as the wafer 38 is rotated as hereinafter described.

Referring next to FIGS. 2-4, in implementation of the present invention the chuck 36 of the wafer support 30 supports a wafer 38 as the wafer 38 is subjected to a wet stripping process for the removal of photoresist (not shown) from the patterned upper surface of the wafer 38, for example. However, it is understood that the wafer support 30 may be used to support the wafer 38 in any other type of process in which a liquid is dispensed onto the wafer for coating of the wafer with the liquid. Initially, the chuck heater 44 is energized to heat the chuck 36 and the wafer 38 to a desired target temperature, such as 40° C., for example. As the shaft 32 rotates the chuck 36 and the wafer 38 supported thereon, the chuck heater 44 maintains the chuck 36 and the wafer 38 at the target temperature. A liquid strip chemical or organic solvent 40, such as ST-250, for example, is next heated to the desired target temperature (40° C. in this case), and then dispensed from the dispenser 42 onto the upper surface of the rotating wafer 38, at the center 38a (FIG. 4) thereof. Due to the rotating motion of the wafer 38, centrifugal force spreads the strip chemical 40 outwardly over the surface of the wafer 38 from the wafer center 38a toward the wafer edge 38b in a spiral pattern, as shown in FIG. 4. As the wafer 38 is rotated by the rotating chuck 36 and shaft 32, the chuck heater 44 continually heats the chuck 36 which, in turn, heats the wafer 38. Accordingly, the temperature of the strip chemical 40 on the wafer 38 is maintained at the elevated target temperature, and thus, the viscosity of the strip chemical 40 is maintained at a relatively low value. This low viscosity of the strip chemical 40 facilitates substantially uniform flow or migration of the strip chemical 40 over the entire surface of the wafer 38, between the wafer center 38a and the wafer edge 38b. The strip chemical 40 removes residual photoresist (not shown) from the surface of the wafer 38, including circuit lines etched in the conductive layer on the wafer 38 in a previous metal etch process. Finally, the wafer 38 is typically rinsed with DI (deionized) water to remove the residual strip chemical 40 and photoresist prior to continued fabrication of integrated circuits on the wafer 38, in conventional fashion.

While the preferred embodiments of the invention have been described above, it will be recognized and understood that various modifications can be made in the invention and the appended claims are intended to cover all such modifications which may fall within the spirit and scope of the invention.

What is claimed is:

1. A method of maintaining a process chemical at a low viscosity during a process, comprising the steps of:
providing a wafer;
heating said wafer to a target temperature;
heating the process chemical to said target temperature;
rotating said wafer; and
dispensing the process chemical onto said wafer.

2. The method of claim 1 wherein said target temperature is about 40° C.

3. The method of claim 1 wherein said heating said wafer to a target temperature comprises the steps of providing a wafer chuck, providing said wafer on said wafer chuck and heating said wafer chuck to said target temperature.

4. The method of claim 3 wherein said target temperature is about 40° C.

5. The method of claim 3 wherein said providing a wafer chuck comprises the step of providing a chuck heater in said wafer chuck and wherein said heating said wafer chuck to said target temperature comprises the step of heating said chuck heater to said target temperature.

6. The method of claim 5 wherein said target temperature is about 40° C.

7. The method of claim 5 wherein said chuck heater comprises a generally inverted cone-shaped heater body.

8. The method of claim 7 wherein said target temperature is about 40° C.

9. A method of enhancing removal of a photoresist from a wafer, comprising the steps of:
providing a wafer;
heating said wafer to a target temperature;
providing a strip chemical;
heating said strip chemical to said target temperature;
rotating said wafer; and
dispensing said strip chemical onto said wafer.

10. The method of claim 9 wherein said target temperature is about 40° C.

11. The method of claim 9 wherein said heating said wafer to a target temperature comprises the steps of providing a wafer chuck, providing said wafer on said wafer chuck and heating said wafer chuck to said target temperature.

12. The method of claim 11 wherein said target temperature is about 40° C.

13. The method of claim 11 wherein said providing a wafer chuck comprises the step of providing a chuck heater in said wafer chuck and wherein said heating said wafer chuck to said target temperature comprises the step of heating said chuck heater to said target temperature.

14. The method of claim 13 wherein said target temperature is about 40° C.

15. The method of claim 13 wherein said chuck heater comprises a generally inverted cone-shaped heater body.

16. The method of claim 15 wherein said target temperature is about 40° C.

17. A wafer support for supporting and heating a wafer, comprising:
a wafer chuck for supporting the wafer; and
a wafer heater provided in said wafer chuck for heating said wafer chuck.

18. The wafer support of claim 17 wherein said wafer heater comprises a heater body having a generally inverted cone-shaped configuration.

19. The wafer support of claim 17 further comprising a shaft and wherein said wafer chuck is carried by said shaft.

20. The wafer support of claim 19 wherein said wafer heater comprises a heater body having a generally inverted cone-shaped configuration.
